(19) United States
(12) Patent Application Publication
(10) Pub. No.: US 2025/0185296 A1
(43) Pub. Date: Jun. 5, 2025

(54) Semiconductor Structures and Methods of Forming Same

(71) Applicant: Taiwan Semiconductor Manufacturing Company, Ltd., Hsin-Chu (TW)

(72) Inventors: Hung-Ju CHOU, Hsinchu (TW); Wei-Yang LEE, Taipei City (TW); Yuan-Ching Peng, Hsinchu (TW); Chih-Ching Wang, Hsinchu (TW)

(21) Appl. No.: 18/524,514

(22) Filed: Nov. 30, 2023

(51) Int. Cl. H01L 29/423; H01L 21/8234; H01L 27/088; H01L 29/06; H01L 29/08; H01L 29/66; H01L 29/775; H01L 29/786

(52) U.S. Cl. CPC H10D 30/6735; H10D 30/014; H10D 30/43; H10D 30/6757; H10D 62/121; H10D 62/151; H10D 64/017; H10D 64/018; H10D 84/0128; H10D 84/013; H10D 84/0147; H10D 84/038; H10D 84/83

(57) ABSTRACT

A method includes providing a workpiece comprising a stack of semiconductor layers including interleaving first semiconductor layers and second semiconductor layers, forming a dummy gate structure to wrap over a channel region of the stack of semiconductor layers, performing a first etching process to selectively recess the second semiconductor layers, forming a gate spacer layer over the dummy gate structure and the stack of semiconductor layers, recessing a source/drain region of the stack of semiconductor layers to form a source/drain opening, performing a second etching process to selectively recess the second semiconductor layers from the source/drain opening to form inner spacer recesses, forming inner spacers in the inner spacer recesses, forming a source/drain feature in the source/drain opening, and replacing the dummy gate structure and the second semiconductor layers with a gate structure.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

For example, as integrated circuit (IC) technologies progress towards smaller technology nodes, multi-gate metal-oxide-semiconductor field effect transistor (multi-gate MOSFET, or multi-gate devices) have been introduced to improve gate control by increasing gate-channel coupling, reducing off-state current, and reducing short-channel effects (SCEs). A multi-gate device generally refers to a device having a gate structure, or portion thereof, disposed over more than one side of a channel region. Gate-all-around (GAA) transistors are examples of multi-gate devices that have become popular and promising candidates for high performance and low leakage applications. A GAA transistor has a gate structure that can extend, partially or fully, around a channel region to provide access to the channel region on two or more sides. Because its gate structure surrounds the channel regions, a GAA transistor may also be referred to as a surrounding gate transistor (SGT) or a Multi-bridge-channel (MBC) transistor.

In a GAA transistor, a source/drain feature may be spaced apart from the channel region due to presence of various gate spacer layers. Thicknesses of the gate spacer layers may vary in different locations, which may impact their protection to the source/drain feature during the fabrication process and/or mitigation of electrical short between the gate structure and the source/drain feature. These may impact the overall performance of the GAA transistor. While conventional GAA transistors are generally adequate to their intended purposes, they are not satisfactory in all aspects.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a flowchart of a method for forming a semiconductor structure, according to one or more aspects of the present disclosure.

FIGS. 2 and 3 illustrate fragmentary perspective views of an exemplary workpiece during various fabrication stages in the method of FIG. 1 according to aspects of the present disclosure.

FIG. 4 illustrates a fragmentary top view of the exemplary workpiece during various fabrication stages in the method of FIG. 1 according to aspects of the present disclosure.

FIGS. 5A, 6A, 7A, 8A, 9A, 10A, 11A, 12A, and 13A illustrate fragmentary cross-sectional views of the exemplary workpiece during a fabrication process according to the method of FIG. 1 along line A-A of FIG. 3 and in region B of FIG. 4, according to one or more aspects of the present disclosure.

FIGS. 6B, 7B, 11B, 11C, 13B, and 13C illustrate enlarged views of a portion B1 of FIGS. 6A, 7A, 11A, 11A, 13A, and 13A, respectively, according to one or more aspects of the present disclosure.

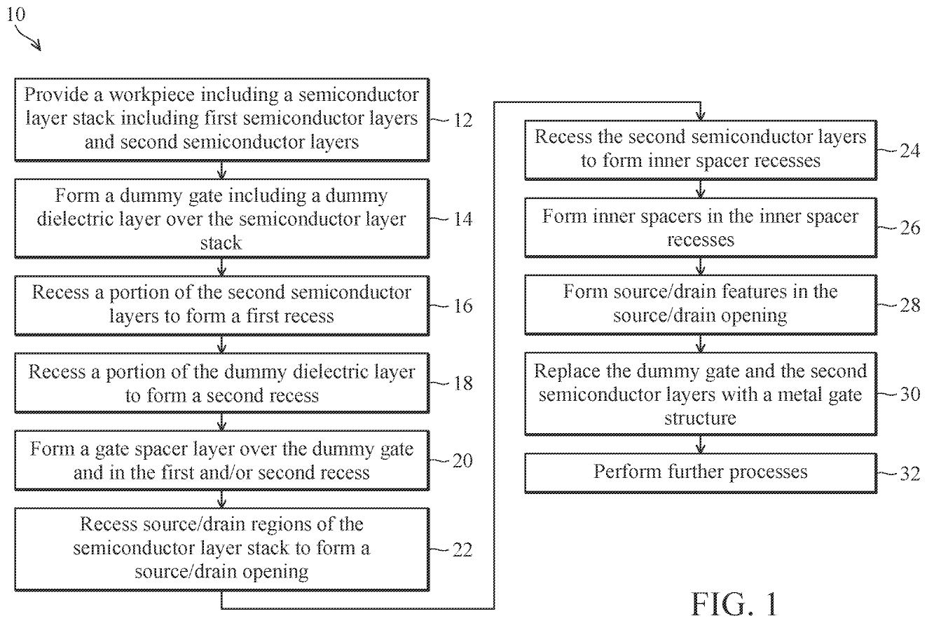

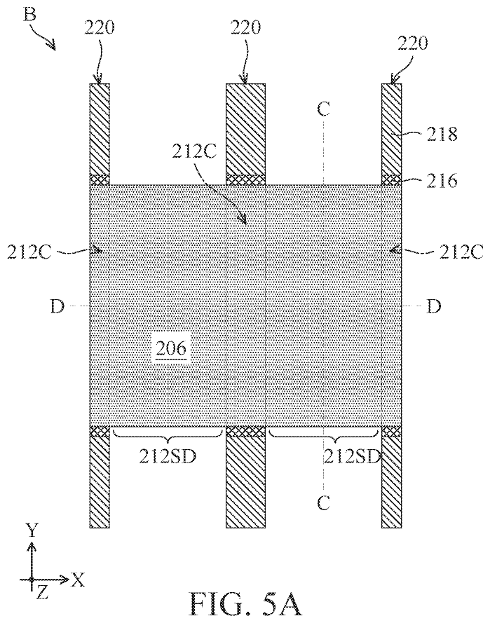

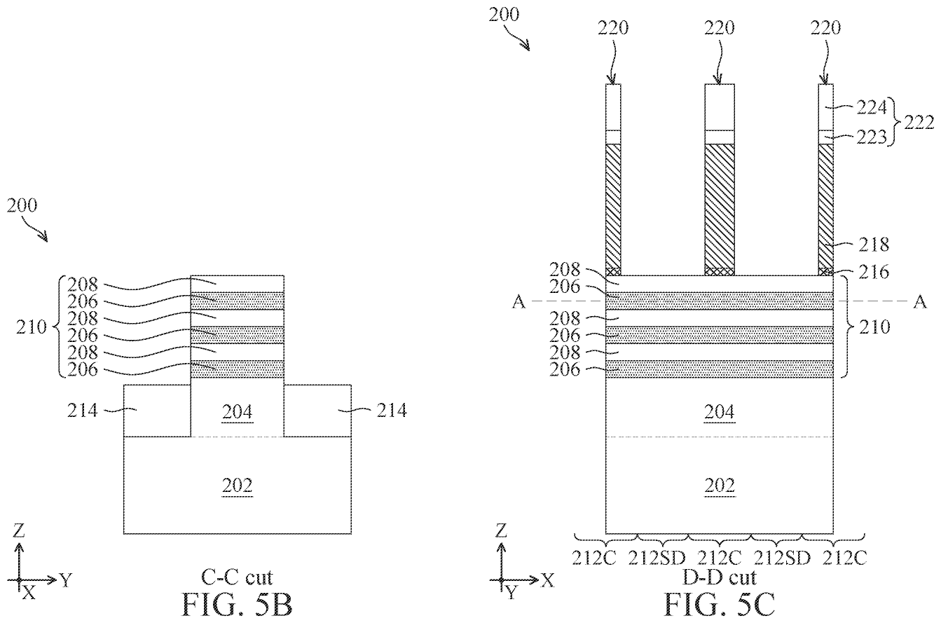

FIGS. 5B, 6C, 7C, and 8B illustrate fragmentary cross-sectional views of the exemplary workpiece during a fabrication process according to the method of FIG. 1 along line C-C of FIGS. 5A, 6A, 7A, and 8A, respectively, according to one or more aspects of the present disclosure.

FIGS. 5C, 6D, 7D, 8C, 9B, 10B, 11D, 12B, 13D, and 13E illustrate fragmentary cross-sectional views of the exemplary workpiece during a fabrication process according to the method of FIG. 1 along line D-D of FIGS. 5A, 6A, 7A, 8A, 9A, 10A, 11A, 12A, 13A, and 13A, respectively, according to one or more aspects of the present disclosure.

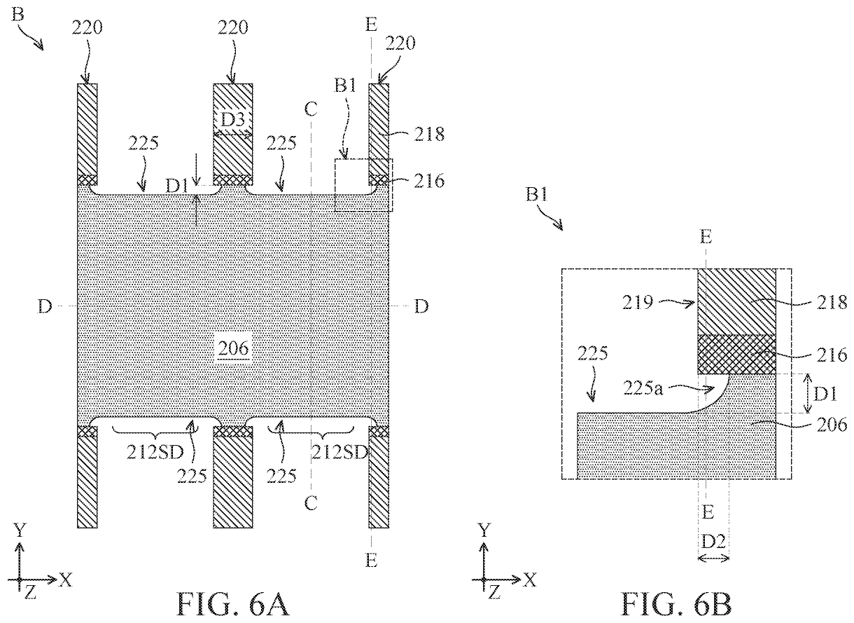

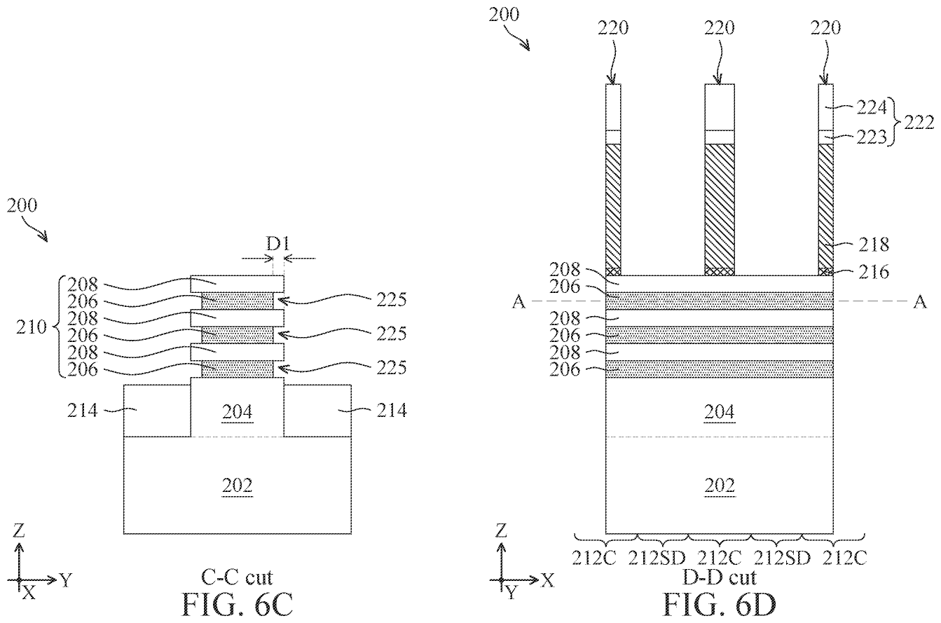

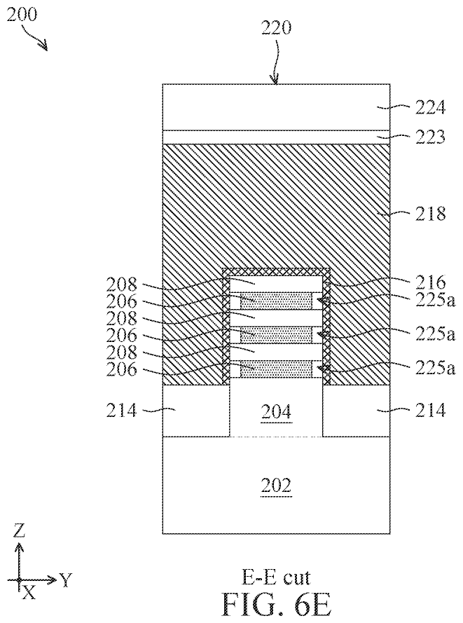

FIGS. 6E, 7E, 8D, 13F, and 13G illustrate fragmentary cross-sectional views of the exemplary workpiece during a fabrication process according to the method of FIG. 1 along line E-E of FIGS. 6A, 7A, 8A, 13B, and 13C, respectively, according to one or more aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art.

The present disclosure is generally related to GAA transistors and fabrication methods, and more particularly to gate spacers having a protruding portion extending into a metal gate structure.

As described above, GAA transistors may also be referred to as SGTs, MBC transistors, nanosheet transistors, or nanowire transistors. They can be either n-type or p-type. GAA devices according to the present disclosure may have channel regions disposed in nanowire channel members, bar-shaped channel members, nanosheet channel members, nanostructure channel members, bridge-shaped channel members, and/or other suitable channel configurations. Gate spacers and/or inner spacer features have been implemented to isolate a gate structure (or sacrificial layers before gate replacement) from a source/drain feature. However, in some existing practices, spacer features may not provide sufficient separation between the source/drain feature and sacrificial layers or the gate structure. For example, when removing the sacrificial layers during channel release processes, portions of the inner spacers may be removed, which reduces thickness of inner spacers and may increase the probability of damaged source/drain features.

The present disclosure provides embodiments of a GAA device structure where sacrificial layers are selectively etched before forming gate spacers. In the method disclosed herein, a dummy gate stack is formed over a stack of semiconductor layers including interleaving channel layers and sacrificial layers. A first selective etching process is performed to the sacrificial layers to form recesses having a portion directly under the dummy gate structure. Gate spacer layers are then deposited over the dummy gate stack, the stack of semiconductor layers, and in the recesses. Because the gate spacer layers also fill in the recesses, gate spacers formed from the gate spacer layers have an increased thickness at an interface with the sacrificial layer. Source/drain recesses are then formed in source/drain regions of the stack of semiconductor layers. A second selective etching process is then performed to the sacrificial layers to form inner spacer recesses, in which inner spacers are formed. After source/drain features are formed in the source/drain recesses, the dummy gate stack and the sacrificial layers are replaced by a metal gate structure. During the gate replacement process, because of the increased thickness of the gate spacers at the interface with the sacrificial layer, possibility of etching through the gate spacers and/or the inner spacers is reduced, which may reduce damages to the source/drain features. In addition, the thickened gate spacers may also reduce electrical short between the metal gate structure and the source/drain features.

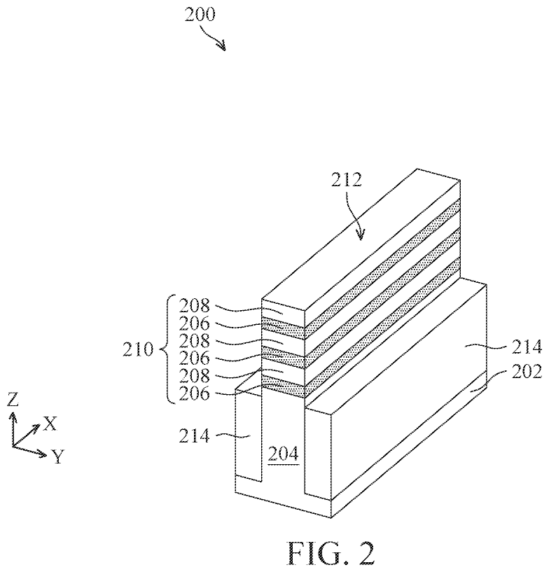

The various aspects of the present disclosure will now be described in more detail with reference to the figures. In that regard, FIG. 1 is a flowchart illustrating a method 10 of forming a semiconductor structure from a workpiece according to embodiments of the present disclosure. Method 10 is merely an example and is not intended to limit the present disclosure to what is explicitly illustrated in method 10. Additional steps can be provided before, during, and after the method 10, and some steps described can be replaced, eliminated, or moved around for additional embodiments of the method. Not all steps are described herein in detail for reasons of simplicity. Method 10 is described below in conjunction with FIG. 2-13G, which are fragmentary perspective, top, or cross-sectional views of a workpiece 200 at different stages of fabrication according to embodiments of the method 10 in FIG. 1. Because the workpiece 200 will be fabricated into a semiconductor structure, the workpiece 200 may be referred to herein as a semiconductor structure 200 as the context requires. For avoidance, the X, Y and Z directions in FIGS. 2-13G are perpendicular to one another. Additionally, throughout the disclosure, like reference numerals may denote like features.

Referring to FIGS. 1 and 2, method 10 includes a block 12 where the workpiece 200 is provided. The workpiece 200 includes a substrate 202 and a fin-shaped structure 212 extending vertically along the Z direction from the substrate 202. The fin-shaped structure 212 extends lengthwise along the X direction. The fin-shaped structure 212 include a base 204 and a semiconductor layer stack 210 disposed over the base 204. The number of the fin-shaped structure 212 shown in FIG. 2 is for illustration purpose only and should not be construed as limiting the scope of the present disclosure.

As shown in FIG. 2, the workpiece 200 includes a substrate 202. In some embodiments, the substrate 202 may be a semiconductor substrate such as a silicon (Si) substrate. The substrate 202 may include various doping configurations depending on design requirements as is known in the art. In embodiments where the semiconductor structure is p-type, an n-type doping profile (i.e., an n-type well or n-well) may be formed on the substrate 202. In some implementations, the n-type dopant for forming the n-type well may include phosphorus (P) or arsenide (As). In embodiments where the semiconductor structure is n-type, a p-type doping profile (i.e., a p-type well or p-well) may be formed on the substrate 202. In some implementations, the n-type dopant for forming the p-type well may include boron (B) or gallium (Ga). The suitable doping may include ion implantation of dopants and/or diffusion processes. The substrate 202 may also include other semiconductors such as germanium (SiGe), silicon carbide (SiC), silicon germanium (SiGe), or diamond. Alternatively, the substrate 202 may include a compound semiconductor and/or an alloy semiconductor. Further, the substrate 202 may optionally include an epitaxial layer (epi-layer), may be strained for performance enhancement, may include a silicon-on-insulator (SOI) or a germanium-on-insulator (GeOI) structure, and/or may have other suitable enhancement features.

In some embodiments, the semiconductor layer stack 210 includes first semiconductor layers 208 (also referred to as channel layers 208) of a first semiconductor composition interleaved by second semiconductor layers 206 (also referred to as sacrificial layers 206) of a second semiconductor composition. The first and second semiconductor composition may be different. In some embodiments, the channel layers 208 include silicon (Si) and the sacrificial layers 206 include silicon germanium (SiGe). It is noted that three (3) layers of the sacrificial layers 206 and three (3) layers of the channel layers 208 are alternately arranged as illustrated in FIG. 2, which is for illustrative purposes only and not intended to be limiting beyond what is specifically recited in the claims. It can be appreciated that any number of semiconductor layers may be formed in the semiconductor layer stack 210. The number of layers depends on the desired number of channels members for the workpiece 200. In some embodiments, the number of the channel layers 208 is between 2 and 10.

In some embodiments, all sacrificial layers 206 may have a substantially uniform first thickness and all of the channel layers 208 may have a substantially uniform second thickness. The first thickness and the second thickness may be identical or different. As described in more detail below, the channel layers 208 or parts thereof may serve as channel member(s) for a subsequently-formed multi-gate device and the thickness of each of the channel layers 208 is chosen based on device performance considerations. The sacrificial layers 206 in channel regions(s) may eventually be removed and serve to define a vertical distance (along the Z direction) between adjacent channel region(s) for a subsequently-formed multi-gate device and the thickness of each of the sacrificial layers 206 is chosen based on device performance considerations.

The layers in the semiconductor layer stack 210 may be deposited using a molecular beam epitaxy (MBE) process, a vapor phase deposition (VPE) process, and/or other suitable epitaxial growth processes. As stated above, in at least some examples, the sacrificial layers 206 include an epitaxially grown silicon germanium (SiGe) layer and the channel layers 208 include an epitaxially grown silicon (Si) layer. In some embodiments, the sacrificial layers 206 and the channel layers 208 are substantially dopant-free (i.e., having an extrinsic dopant concentration from about 0 cm⁻³ to about 1×10¹⁷ cm⁻³), where for example, no intentional doping is performed during the epitaxial growth processes for the semiconductor layer stack 210.

The fin-shaped structure 212 may be formed from the deposited layers of the semiconductor layer stack 210 and the substrate 202. A hard mask layer may be deposited over the deposited layers of the semiconductor layer stack 210 to form an etch mask. The hard mask layer may be a single layer or a multi-layer. For example, the hard mask layer may include a pad oxide layer and a pad nitride layer over the pad oxide layer. The fin-shaped structure 212 may be patterned from the deposited layers of the semiconductor layer stack 210 and the substrate 202 using a lithography process and an etch process. The lithography process may include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etch process may include dry etching (e.g., RIE etching), wet etching, and/or other etching methods. The etch process forms trenches extending through the semiconductor layer stack 210 and extending through a portion of the substrate 202 to form the base 204. The trenches define the fin-shaped structure 212. In some implementations, double-patterning or multi-patterning processes may be used to define fin-shaped structures that have, for example, pitches smaller than what is otherwise obtainable using a single, direct photolithography process. For example, in one embodiment, a material layer is formed over a substrate and patterned using a photolithography process. Spacers are formed alongside the patterned material layer using a self-aligned process. The material layer is then removed, and the remaining spacers, or mandrels, may then be used to pattern the fin-shaped structure 212 by etching the deposited layers of the semiconductor layer stack 210. As shown in FIG. 2, the fin-shaped structure 212, along with the sacrificial layers 206 and the channel layers 208 therein, extends vertically along the Z direction and lengthwise along the X direction.

The workpiece 200 may include isolation features 214 adjacent the fin-shaped structure 212. In some embodiments, the isolation features 214 may be formed in the trenches to isolate the fin-shaped structures 212 from a neighboring active region. The isolation feature 214 may also be referred to as a shallow trench isolation (STI) feature 214. By way of example, in some embodiments, a dielectric layer is first deposited over the substrate 202, filling the trenches with the dielectric layer. In some embodiments, the dielectric layer may include silicon oxide, silicon nitride, silicon oxynitride, fluorine-doped silicate glass (FSG), a low-k dielectric, combinations thereof, and/or other suitable materials. In various examples, the dielectric layer may be deposited by a CVD process, a subatmospheric CVD (SACVD) process, a flowable CVD process, a spin-on coating process, and/or other suitable process. The deposited dielectric material is then thinned and planarized, for example by a chemical mechanical polishing (CMP) process. The planarized dielectric layer is further recessed or pulled-back by a dry etching process, a wet etching process, and/or a combination thereof to form the STI feature 214. The fin-shaped structure 212 rises above the STI feature 214 after the recessing.

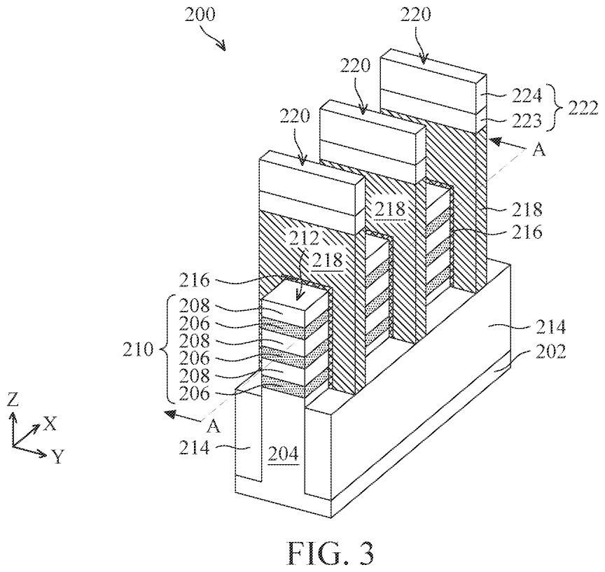

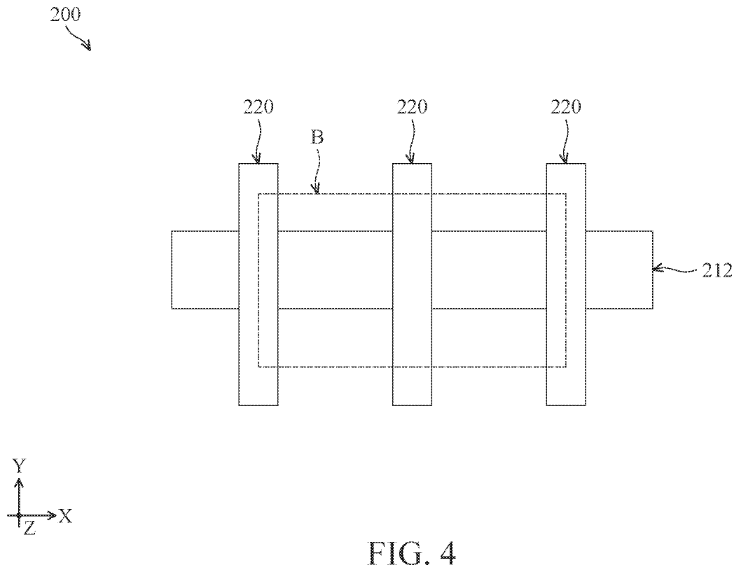

Referring to FIGS. 1 and 3-5C, method 10 includes a block 14 where a dummy gate stack 220 is formed over a channel region 212C of the fin-shaped structure 212. FIGS. 3 and 4 show a fragmentary perspective view and a fragmentary top view of the workpiece 200 at block 14, respectively, according to aspects of the present disclosure. FIG. 5A illustrates a fragmentary cross-sectional view of the workpiece 200 along line A-A of FIG. 3 and in region B of FIG. 4. FIGS. 5B and 5C illustrate fragmentary cross-sectional views of the workpiece 200 along line C-C and line D-D of FIG. 5A, respectively. The numbers of the dummy gate stacks 220 shown in FIGS. 3 and 4 are for illustration purpose only and should not be construed as limiting the scope of the present disclosure.

In some embodiments, a gate replacement process (or gate-last process) is adopted where the dummy gate stack 220 serves as a placeholder to undergo various processes and is to be removed and replaced by the functional metal gate structure. Other processes and configuration are possible. In some embodiments, the dummy gate stack 220 is formed over the fin-shaped structure 212 and the fin-shaped structure 212 may be divided into channel regions 212C underlying the dummy gate stacks 220 and source/drain regions 212SD that do not underlie the dummy gate stacks 220. The channel regions 212C are adjacent the source/drain regions 212SD. As shown in FIG. 5C, the channel region 212C is disposed between two source/drain regions 212SD along the X direction. As shown in FIGS. 5A-5C, the sacrificial layers 206 and the channel layers 208 in the channel regions 212C vertically overlap and have the same shapes and dimensions in different horizontal planes.

The formation of the dummy gate stack 220 may include forming layers in the dummy gate stack 220 and patterning these layers. Referring to FIG. 3, a dummy dielectric layer 216, a dummy electrode layer 218, and a gate-top hard mask layer 222 may be blanketly formed over the workpiece 200. In the illustrated embodiment, the dummy dielectric layer 216 is formed as a blanket layer over top and sidewall surfaces of the semiconductor layer stack 210 but not on top surfaces of the isolation structures 214. In an alternative embodiment, the dummy dielectric layer 216 is formed on the top and sidewall surfaces of the semiconductor layer stack 210 and over the top surfaces of the isolation structures 214. The dummy dielectric layer 216 may provide protection to the semiconductor layer stack 210. The dummy dielectric layer 216 may be formed by various methods such as chemical oxidation of silicon, thermal oxidation of silicon, ozone oxidation of silicon, atomic layer deposition (ALD), chemical vapor deposition (CVD), physical vapor deposition (PVD), or other suitable methods. The dummy dielectric layer 216 may include silicon oxide.

Thereafter, the dummy electrode layer 218 may be deposited over the dummy dielectric layer 216 using a CVD process, an ALD process, or other suitable processes. In some instances, the dummy electrode layer 218 may include polysilicon. For patterning purposes, the gate-top hard mask layer 222 may be deposited on the dummy electrode layer 218 using a CVD process, an ALD process, or other suitable processes. The gate-top hard mask layer 222, the dummy electrode layer 218 and the dummy dielectric layer 216 may then be patterned to form the dummy gate stack 220, as shown in FIG. 3. For example, the patterning process may include a lithography process (e.g., photolithography or e-beam lithography) which may further include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etching process may include dry etching (e.g., RIE etching), wet etching, and/or other etching methods. In some embodiments, the gate-top hard mask layer 222 may include a silicon oxide layer 223 and a silicon nitride layer 224 over the silicon oxide layer 223. As shown in FIG. 5C, no dummy gate stack 220 is disposed over the source/drain region 212SD of the fin-shaped structure 212.

Referring to FIGS. 1 and 6A-6E, method 10 includes a block 16 where a portion of the sacrificial layers 206 is recessed to form first recesses 225. FIG. 6A illustrates a fragmentary cross-sectional view of the workpiece 200 at block 16 along line A-A of FIG. 3 and in region B of FIG. 4. FIG. 6B illustrates an enlarged view of a portion B1 of FIG. 6A. FIGS. 6C, 6D, and 6E illustrate fragmentary cross-sectional views of the workpiece 200 along line C-C, line D-D, and line E-E of FIG. 6A, respectively. As illustrated in FIGS. 6A and 6B, line E-E is along the Y direction, close to an edge 219 of the dummy electrode layer 218 and is across the dummy dielectric layer 216, the dummy electrode layer 218, and a portion 225a of the first recesses 225.

In some embodiments, the recessing of the sacrificial layers 206 includes performing a first etching process to selectively and partially recess the sacrificial layers 206. In some embodiments, the selective recessing may be a selective isotropic etching process (e.g., a selective dry etching process or a selective wet etching process), and the extent at which the sacrificial layers 206 are recessed is controlled by duration of the etching process. The selective dry etching process may include use of one or more fluorine-based etchants, such as fluorine gas or hydrofluorocarbons. The selective wet etching process may include use of a first solution including hydrogen fluoride (HF), hydrogen peroxide (H₂O₂), hydrochloric acid (HCl), or a combination thereof. In some embodiments, the first etching process may include a wet etching process. In some embodiments, the dummy dielectric layer 216 remains significantly unetched during the selective recessing of the sacrificial layers 206.

Referring to FIGS. 6A and 6B, in some embodiments, the first recesses 225 have a bar-shape extending lengthwise along the X direction and with two half-rounded ends. In some embodiments, the first recesses 225 include a portion 225a disposed between the dummy gate stack 220 and the sacrificial layer 206 along the Y direction. The portion 225a extends into the sacrificial layer 206 and may have any suitable shapes, such as a triangle shape, a triangle shape having a rounded side, or a fan shape. In some embodiments, the first recesses 225 have a depth D1 of about 1 nm to about 3 nm along the Y direction. The portion 225a of the first recesses 225 may have the depth D1 along the Y direction and a depth D2 along the X direction. D2 may be about 1 nm to about 4 nm. If D1 and/or D2 are smaller than the lower bounds of the ranges, the benefits of this disclosure may not exist. If D1 and/or D2 are greater than the higher bounds of the ranges, connection between the dummy dielectric layer 216 and the sacrificial layers 206 may be too small, which may cause the dummy gate stack 220 to collapse. A ratio of the depth D2 to a width D3 of the dummy electrode layer 218 along the X direction is about 0.05 to about 0.3. If the ratio is smaller than the lower bound of the range, the benefits of this disclosure may not exist. If the ratio is greater than the higher bound of the range, connection between the dummy dielectric layer 216 and the sacrificial layers 206 may be too small, which may cause the dummy gate stack 220 to collapse.

Referring to FIG. 6C, in embodiments, the first recesses 225 are each disposed between a channel layer 208 and an adjacent channel layer 208 (or the base 204). In the cross-sectional view along line C-C, sidewalls of the sacrificial layers 206 are recessed from sidewalls of the channel layers 208 (or the base 204) by about D1. Thus, the fin-shaped structure 212 has a wavy profile as shown in FIG. 6C. Because the dummy dielectric layer 216 remains significantly unetched during the selective recessing of the sacrificial layers 206, the cross-sectional view in FIG. 6D remains significantly the same as FIG. 5C.

Referring to FIG. 6E, in some embodiments, the portions 225a of the first recesses 225 are directly under the dummy electrode layer 218. In some embodiments, the portions 225a are each disposed between a channel layer 208 and an adjacent channel layer 208 (or the base 204). Because the dummy dielectric layer 216 remains significantly unetched during the selective recessing of the sacrificial layers 206, the dummy dielectric layer 216 surrounds the semiconductor layer stack 210, the portions 225a of the first recesses 225, and a top portion of sidewalls of the base 204.

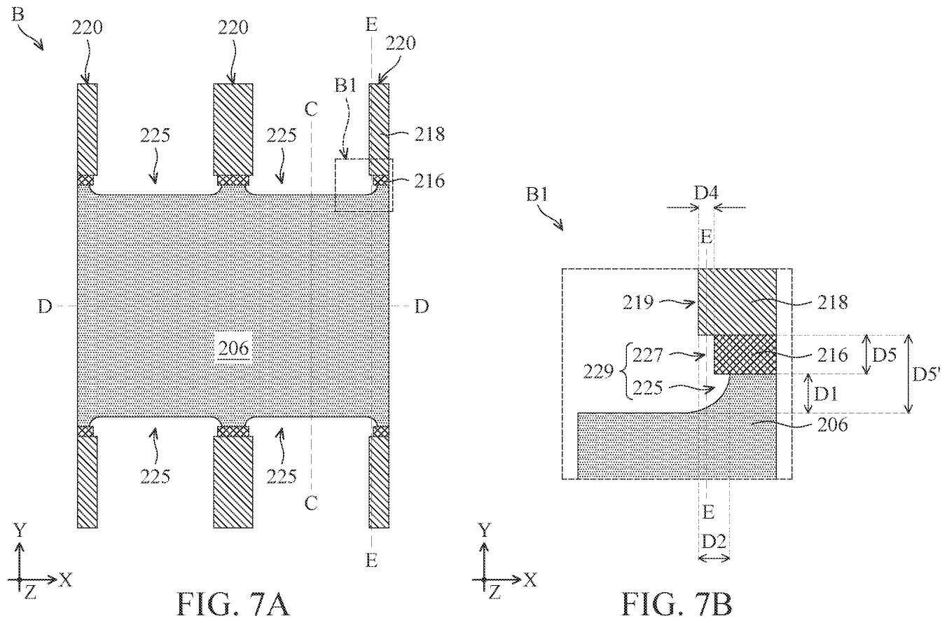

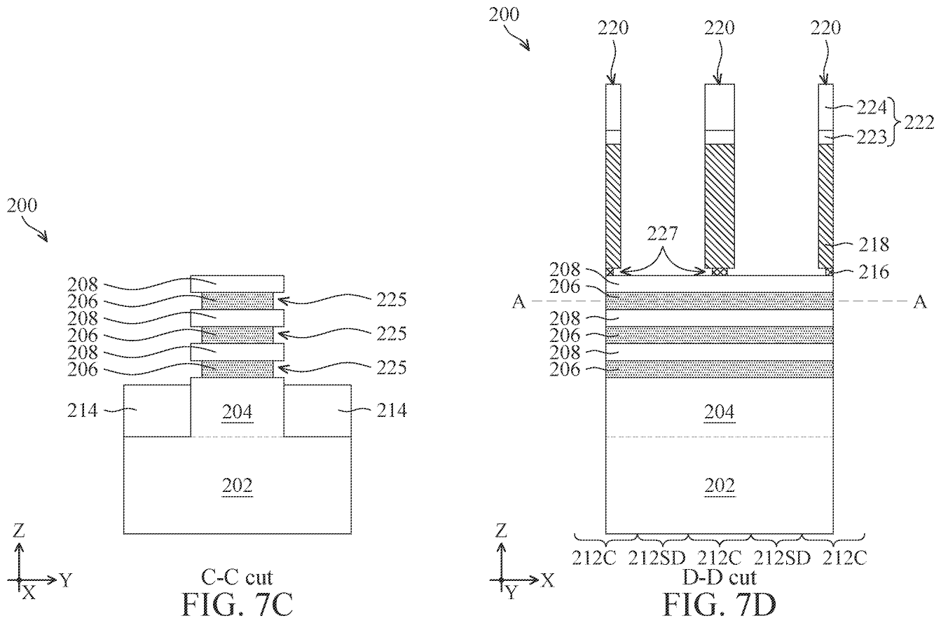

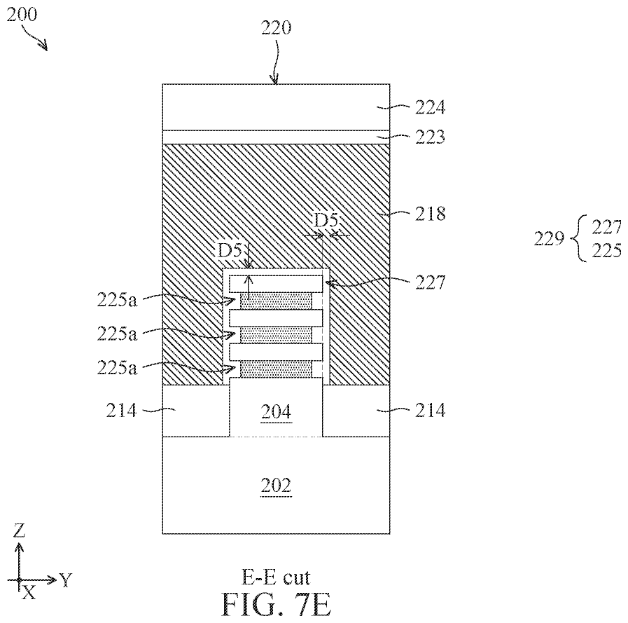

Referring to FIGS. 1 and 7A-7E, method 10 includes a block 18 where a portion of the dummy dielectric layer 216 is recessed to form second recesses 227. FIG. 7A illustrates a fragmentary cross-sectional view of the workpiece 200 at block 18 along line A-A of FIG. 3 and in region B of FIG. 4. FIG. 7B illustrates an enlarged view of a portion B1 of FIG. 7A. FIGS. 7C, 7D, and 7E illustrate fragmentary cross-sectional views of the workpiece 200 along line C-C, line D-D, and line E-E of FIG. 7A, respectively. As illustrated in FIGS. 7A and 7B, line E-E is along the Y direction, close to an edge 219 of the dummy electrode layer 218 and is across the dummy electrode layer 218, the second recesses 227, and the portion 225a of the first recesses 225. The operations of the block 18 are optional and may be omitted. In some embodiments, the operations of the block 18 are performed before the operations of the block 16. In some embodiments, the operations of the blocks 16 and 18 are combined.

In some embodiments, the recessing of the dummy dielectric layer 216 includes performing a second etching process. The second etching process may selectively and partially recess the dummy dielectric layer 216. In some embodiments, the selective recessing may be a selective isotropic etching process (e.g., a selective dry etching process or a selective wet etching process), and the extent at which the dummy dielectric layer 216 is recessed is controlled by duration of the etching process. The selective dry etching process may include use of one or more fluorine-based etchants, such as fluorine gas or hydrofluorocarbons. The selective wet etching process may include use of a second solution including hydrogen fluoride (HF), hydrogen peroxide (H₂O₂), hydrochloric acid (HCl), or a combination thereof. The second solution may be different from the first solution (e.g., in composition, in concentration of a component). In some embodiments, the second etching process may include a wet etching process. In some other embodiments, the first etching process and the second etching process are combined as one etching process using a same etching fluid including HF, H₂O₂, HCl, or a combination thereof.

Referring to FIG. 7B, a depth D4 of the second recess 227 along the X direction may be about 0.5 nm to about 2 nm. If D4 is smaller than the lower bound of the range, the benefits of the block 18 may be too small. If D4 is greater than the higher bound of the range, connection between the dummy electrode layer 218 and the semiconductor layer stack 210 may be too small, which may cause the dummy gate stack 220 to collapse. D4 may be equal to, greater than, or smaller than D2. In some embodiments, D4 is smaller than D2. A width D5 of the second recesses 227 along the Y direction may be about the same as a thickness of the dummy dielectric layer 216 and may be about 0.5 nm to about 2.5 nm. The second recesses 227 may merge with the first recesses 225 as depicted and be referred to as recesses 229. The recesses 229 may have a stepped profile with a rounded side as shown in FIG. 7B. A width D5′ of the recess 229 along the Y direction may be a sum of D5 and D1.

In the depicted embodiment, the dummy dielectric layer 216 is not disposed over the fin-shaped structure 212 in the source/drain regions 212SD. Thus, the cross-sectional view along line C-C as shown in FIG. 7C may be significantly the same as in FIG. 6C. Referring to FIG. 7D, a difference from FIG. 6D includes that the dummy dielectric layer 216 under the dummy electrode layer 218 is recessed by about D4 (not depicted in FIG. 7D) along the X direction. The second recesses 227 may be disposed between the dummy electrode layer 218 and the fin-shaped structure 212.

Referring to FIG. 7E, each of the second recesses 227 may be continuous and surround a top surface and sidewalls of the fin-shaped structure 212. In some embodiments, the second recesses 227 are directly under the dummy electrode layer 218. Each of the second recesses 227 may merge with the portions 225a of the first recesses 225 under a same dummy electrode layer 218. The second recess 227 may have the width D5 along the Y direction and/or along the Z direction as depicted.

For the purpose of simplicity, unless explicitly described, the following figures illustrate subsequent processes after the operations of the block 16 when the operations of the block 18 are omitted. However, it is understood that when the operations of the block 18 are not omitted, after the operations of the block 18, the workpiece 200 goes under similar subsequent processes as described below.

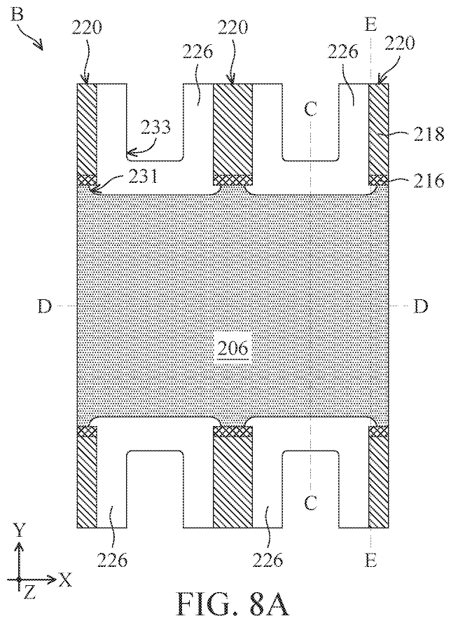

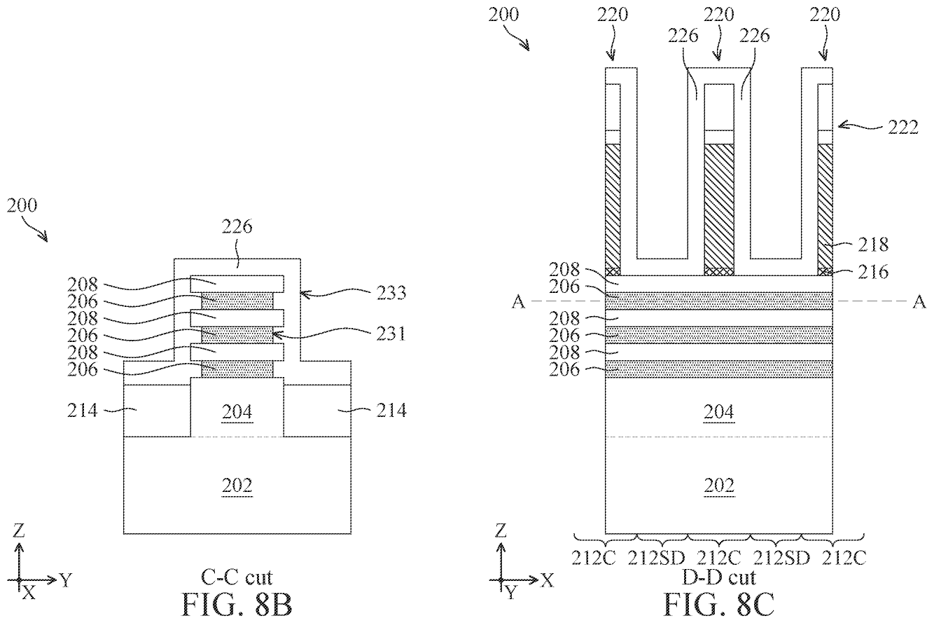

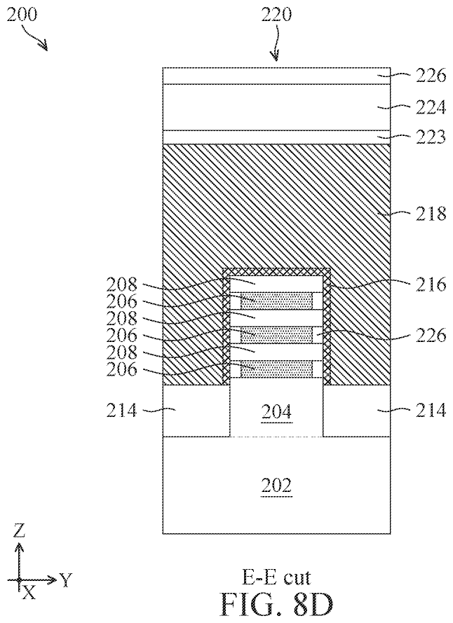

Referring to FIGS. 1 and 8A-8C, method 10 includes a block 20 where a gate spacer layer 226 is deposited over the dummy gate stack 220 and the source/drain regions 212SC of the fin-shaped structure 212. FIG. 8A illustrates a fragmentary cross-sectional view of the workpiece 200 at block 20 along line A-A of FIG. 3 and in region B of FIG. 4. FIGS. 8B, 8C, and 8D illustrate fragmentary cross-sectional views of the workpiece 200 along line C-C, line D-D, and line E-E of FIG. 8A, respectively.

In some embodiments, the gate spacer layer 226 is deposited over the workpiece 200, such as over top surfaces and sidewalls of the dummy gate stack 220 and over the source/drain regions 212C of the fin-shaped structure 212. In the depicted embodiment, the gate spacer layer 226 fills the first recesses 225. In some other embodiments, the gate spacer layer 226 fills the first recesses 225 and the second recesses 227. Thus, an inside surface 231 of the gate spacer layer 226 trace the shapes of the first recesses 225 and/or the second recesses 227. Because the depth D1 of the first recesses 225 is relatively small compared to a thickness of the gate spacer layer 226, an outside surface 233 of the gate spacer layer 226 may be significantly smooth (e.g., not reflecting shapes of the corresponding inside surface 231) as shown in FIGS. 8A and 8B. A portion of the gate spacer layer 226 may be disposed between a channel layer 208 and an adjacent channel layer 208 or the base 204 as shown in FIGS. 8B and 8D. In some embodiments, a portion of the gate spacer layer 226 is disposed directly under the dummy gate stack 220 as shown in FIG. 8D. The gate spacer layer 226 may be a single layer or a multi-layer. The gate spacer layer 226 may include silicon carbonitride, silicon oxycarbide, silicon oxycarbonitride, or silicon nitride. In some implementations, the gate spacer layer 226 may be deposited over the dummy gate stack 220 using processes such as, a CVD process, a subatmospheric CVD (SACVD) process, an ALD process, or other suitable process.

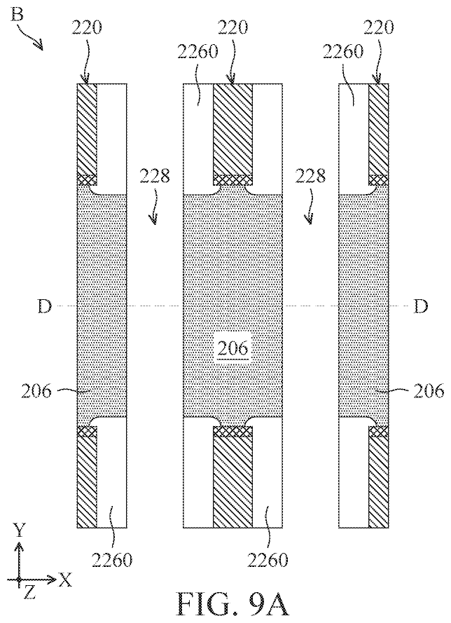

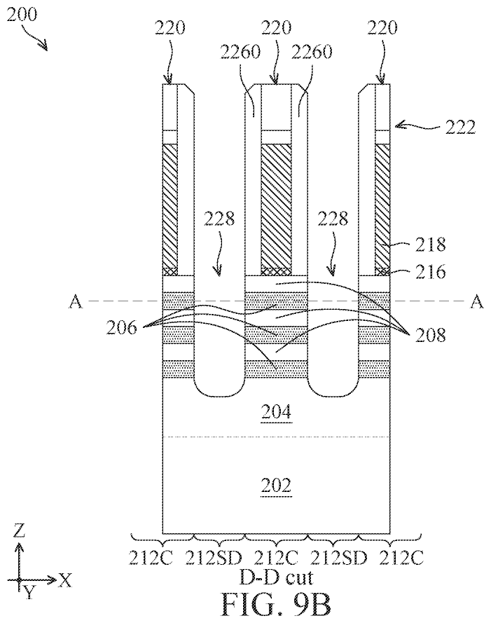

Referring to FIGS. 1 and 9A-9B, method 10 includes a block 22 where a source/drain region 212SD of the fin-shaped structure 212 is recessed to form a source/drain trench 228. FIG. 9A illustrates a fragmentary cross-sectional view of the workpiece 200 at block 22 along line A-A of FIG. 3 and in region B of FIG. 4. FIG. 9B illustrates a fragmentary cross-sectional view of the workpiece 200 along line D-D of FIG. 9A.

As shown in FIG. 9B, the recess at block 22 may remove the top facing portion of the gate spacer layer 226 to form gate spacers 2260 disposed along sidewalls of the dummy gate stack 220. In some embodiments, the source/drain regions 212SD that are not covered by the dummy gate stack 220 are etched by a dry etch or a suitable etching process to form the source/drain trenches 228. For example, the dry etch process may implement an oxygen-containing gas, a fluorine-containing gas (e.g., CF₄, SF₆, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas, other suitable gases and/or plasmas, and/or combinations thereof. In some embodiments represented in FIGS. 9A and 9B, the source/drain regions 212SD of the fin-shaped structure 212 are recessed to expose sidewalls of the sacrificial layers 206 and the channel layers 208. In some implementations, the source/drain trenches 228 extend below the stack 210 into the base 204. As shown in FIGS. 9A and 9B, the sacrificial layers 206 and channel layers 208 in the source/drain region 212SD are removed at block 22, exposing the base 204 and sidewalls of the sacrificial layers 206 and channel layers 208.

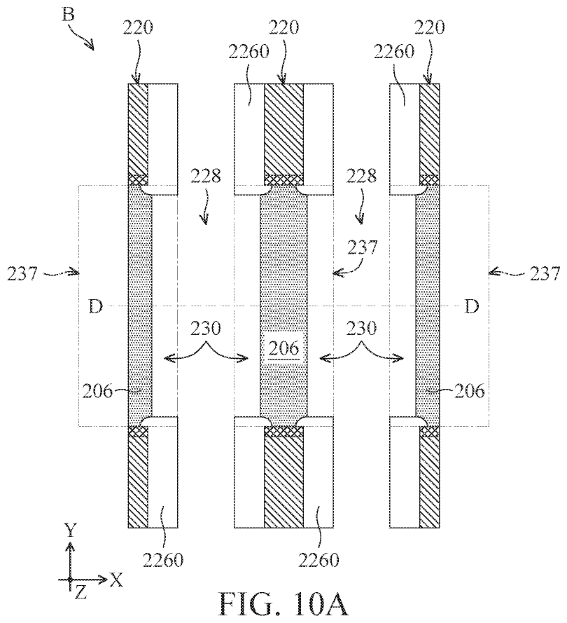

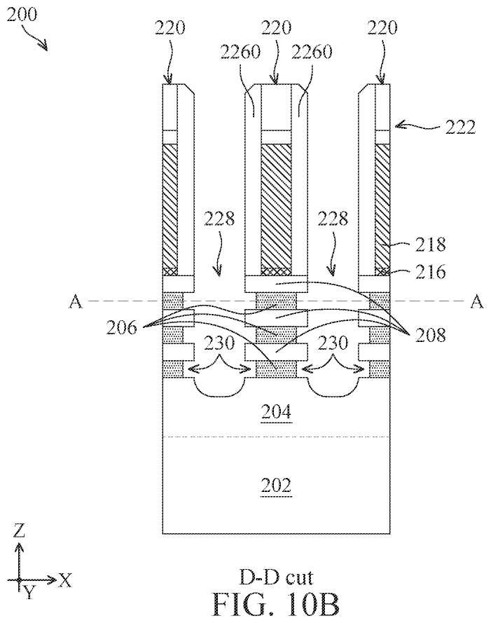

Referring to FIGS. 1 and 10A-10B, method 10 includes a block 24 where the sacrificial layers 206 are selectively and partially recessed to form inner spacer recesses 230. FIG. 10A illustrates a fragmentary cross-sectional view of the workpiece 200 at block 24 along line A-A of FIG. 3 and in region B of FIG. 4. FIG. 10B illustrates a fragmentary cross-sectional view of the workpiece 200 along line D-D of FIG. 10A.

The sacrificial layers 206 exposed in the source/drain trenches 228 are selectively and partially recessed to form inner spacer recesses 230 while the gate spacers 2260, the exposed portion of the base 204, and the channel layers 208 are substantially unetched. For example, the dashed rectangles 237 in FIG. 10A illustrate the top view positions of the channel layers 208. In an embodiment where the channel layers 208 consist essentially of silicon (Si) and sacrificial layers 206 consist essentially of silicon germanium (SiGe), the selective recess of the sacrificial layers 206 may be performed using a selective wet etch process or a selective dry etch process. The selective and partial recess of the sacrificial layers 206 may include a SiGe oxidation process followed by a SiGe oxide removal. In such embodiments, the SiGe oxidation process may include use of ozone. In some other embodiments, the selective dry etching process may include use of one or more fluorine-based etchants, such as fluorine gas or hydrofluorocarbons. The selective wet etching process may include an APM etch (e.g., ammonia hydroxide-hydrogen peroxide-water mixture).

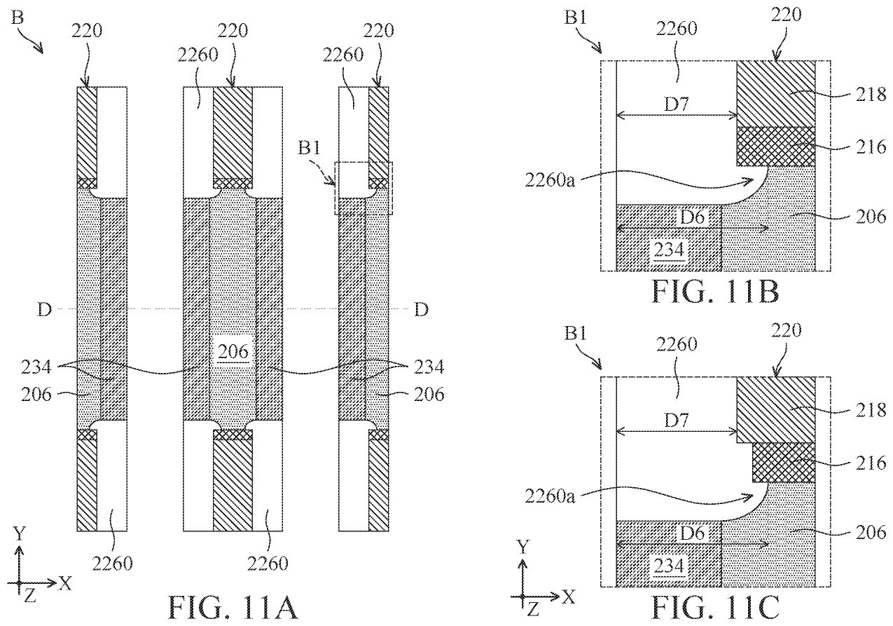

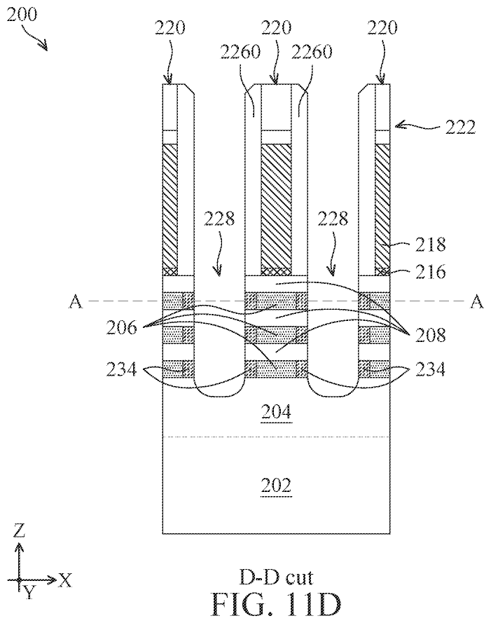

Referring to FIGS. 1 and 11A-11D, method 10 includes a block 26 where inner spacers 234 are formed in the inner spacer recesses 230. FIG. 11A illustrates a fragmentary cross-sectional view of the workpiece 200 at block 26 along line A-A of FIG. 3 and in region B of FIG. 4. FIGS. 11B and 11C illustrate enlarged views of a portion B1 of FIG. 11A according to various aspects of the present disclosure. FIG. 11D illustrates a fragmentary cross-sectional view of the workpiece 200 along line D-D of FIG. 11A.

While not shown explicitly, operation at block 26 may include deposition of an inner spacer material over the workpiece 200 and etching back the inner spacer material to form inner spacer features 234 in the inner spacer recesses 230. In some embodiments, after the inner spacer recesses 230 are formed, the inner spacer material is deposited over the workpiece 200, including over the inner spacer recesses 230. The inner spacer material may include metal oxides, silicon oxide, silicon oxycarbonitride, silicon nitride, silicon oxynitride, carbon-rich silicon carbonitride, or a low-k dielectric material. The metal oxides may include aluminum oxide, zirconium oxide, tantalum oxide, yttrium oxide, titanium oxide, lanthanum oxide, or other suitable metal oxide. While not explicitly shown, the inner spacer material may be a single layer or a multilayer. In some implementations, the inner spacer material may be deposited using CVD, PECVD, SACVD, ALD or other suitable methods. The inner spacer material is deposited into the inner spacer recesses 230 as well as over the sidewalls of the channel layers 208 exposed in the source/drain trenches 228. The deposited inner spacer material is then etched back to remove the inner spacer material from the sidewalls of the channel layers 208 to form the inner spacer features 234 in the inner spacer recesses 230. At block 26, the inner spacer material 232 may also be removed from the top surfaces and/or sidewalls of the gate-top hard mask layer 222 and the gate spacers 2260. In some implementations, the etch back operations performed at block 26 may include use of hydrogen fluoride (HF), fluorine gas (F₂), hydrogen (H₂), ammonia (NH₃), nitrogen trifluoride (NF₃), or other fluorine-based etchants.

As shown in FIGS. 11A and 11D, each of the inner spacer features 234 is in direct contact with the recessed sacrificial layers 206 and is disposed between two neighboring channel layers 208. That is, the inner spacer features 234 interleave the channel layers 208. In some embodiments, referring to FIG. 11B, the operations of the block 18 is omitted, the gate spacer 2260 includes a protruding portion 2260a that fills the portion 225a of the first recess 225 in FIG. 6B. Thus, the protruding portion 2260a tracks the shape and dimensions of the portion 225a. For example, the protruding portion 2260a may has a triangle shape, a triangle shape having a rounded side, or a fan shape as shown in FIG. 11B. In such embodiments, the protruding portion 2260a extends into the sacrificial layer 206 and directly contacts the dummy dielectric layer 216. A thickness D6 of the gate spacer 2260 adjacent to the sacrificial layer 206 and the inner spacer 234 is greater than a thickness D7 of the gate spacer 2260 extending along the dummy electrode layer 218. D6 and D7 are along the X direction. D6 may be greater than D7 by about 1 nm to about 4 nm. In some embodiments, referring to FIG. 11C, the operations of the block 18 is not omitted, the gate spacer 2260 includes a protruding portion 2260a that fills a portion of the recess 229 of in FIG. 7B. Thus, the protruding portion 2260a tracks the shape and dimensions of the portion of the recess 229. In such embodiments, the protruding portion 2260a extends into the sacrificial layer 206 and directly contact the dummy dielectric layer 216 and the dummy electrode layer 218. The protruding portion 2260a may have a stepped profile with a rounded side as shown in FIG. 11C. The thicknesses D6 and D7 may be the same as described in FIG. 11B.

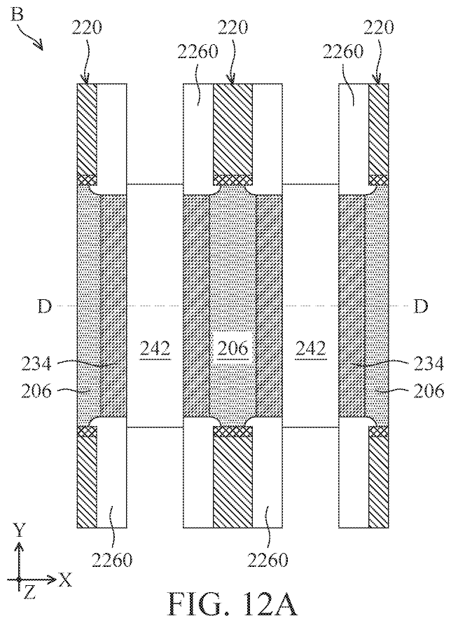

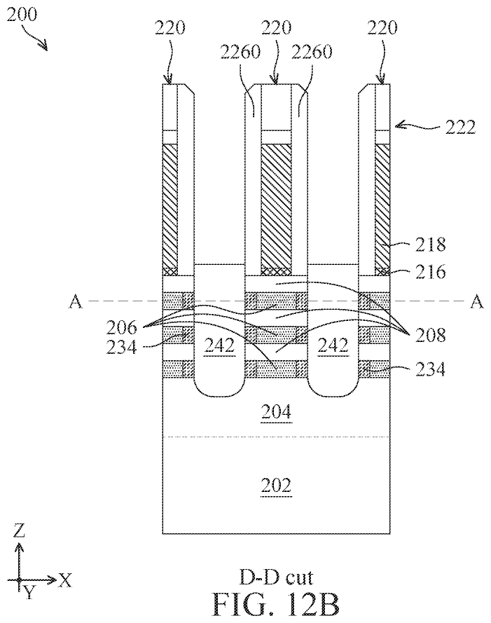

Referring to FIGS. 1 and 12A-12B, method 10 includes a block 28 where source/drain features 242 are formed in the source/drain trenches 228. FIG. 12A illustrates a fragmentary cross-sectional view of the workpiece 200 at block 28 along line A-A of FIG. 3 and in region B of FIG. 4. FIG. 12B illustrates a fragmentary cross-sectional view of the workpiece 200 along line D-D of FIG. 12A.

In some embodiments, the source/drain features 242 may be formed using an epitaxial process, such as vapor-phase epitaxy (VPE), ultra-high vacuum CVD (UHV-CVD), molecular beam epitaxy (MBE), and/or other suitable processes. The epitaxial growth process may use gaseous and/or liquid precursors, which interact with the composition of the base 204 as well as the channel layers 208. The source/drain features 242 may be doped with n-type dopants and/or p-type dopants. Example n-type source/drain features may include Si, GaAs, GaAsP, SiP, or other suitable material and may be in-situ doped during the epitaxial process by introducing an n-type dopant, such as phosphorus (P), arsenic (As), or both. When the source/drain features 242 are not in-situ doped with an n-type dopant, an implantation process (i.e., a junction implant process) may be performed to dope the source/drain features 242 with an n-type dopant. Example p-type source/drain features may include Si, Ge, AlGaAs, SiGe, boron-doped SiGe, or other suitable material and may be in-situ doped during the epitaxial process by introducing a p-type dopant. When the source/drain features 242 are not in-situ doped with a p-type dopant, an implantation process (i.e., a junction implant process) may be performed to dope the source/drain features 242 with a p-type dopant. In some embodiments, the source/drain features 242 include more than one epitaxial semiconductor layer, where the epitaxial semiconductor layers may include the same or different materials and/or the same or different dopant concentrations.

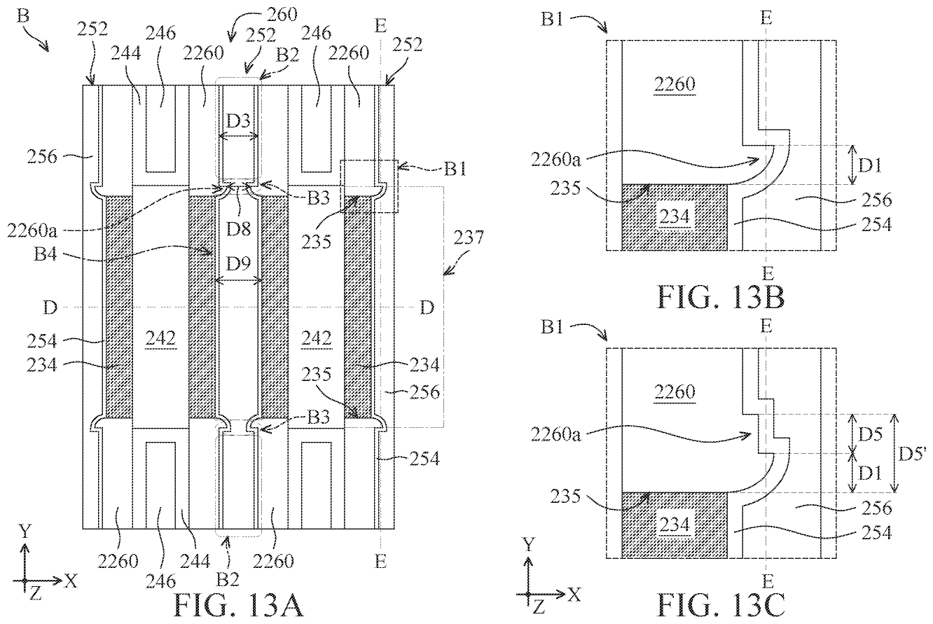

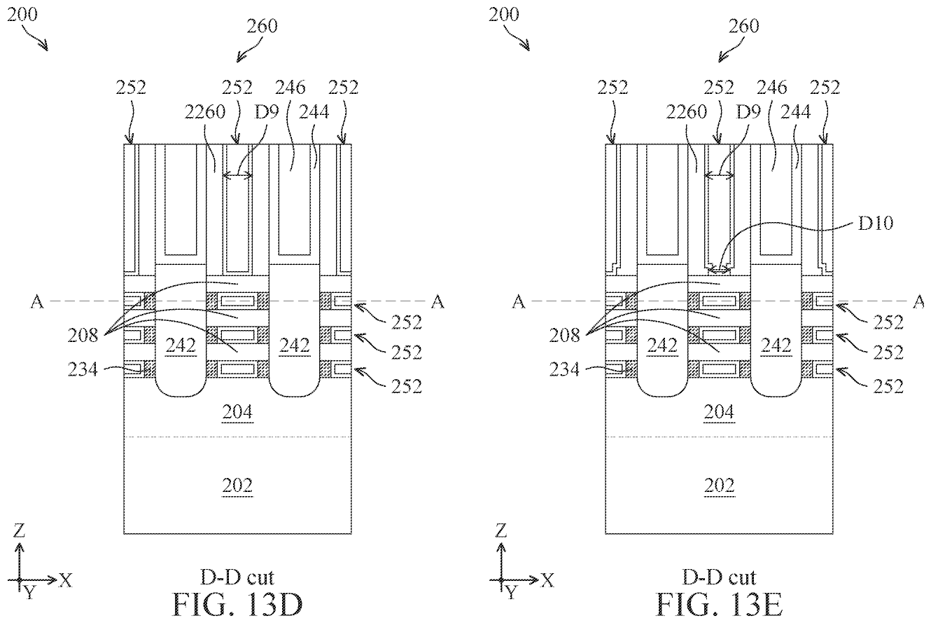

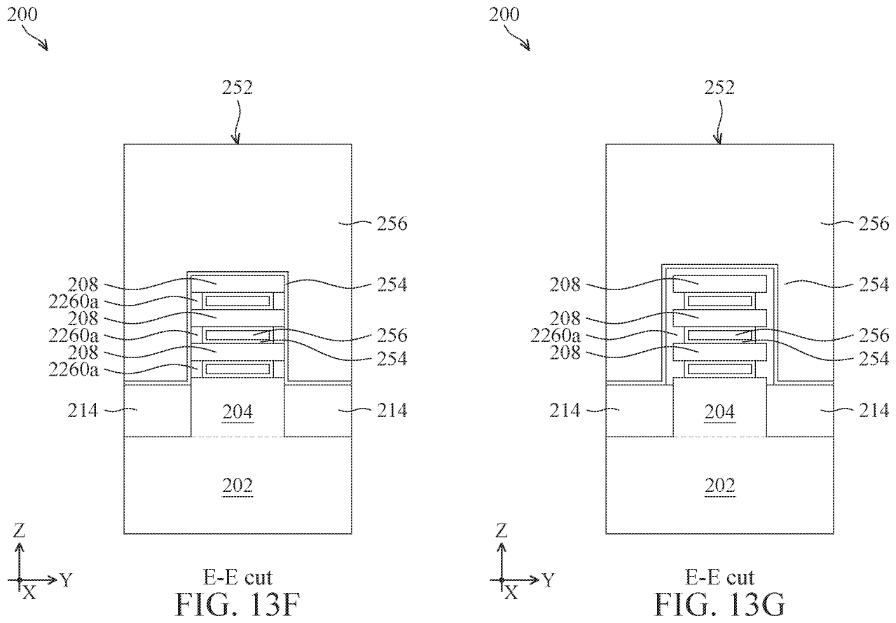

Referring to FIGS. 1 and 13A-13G, method 10 includes a block 30 where the dummy gate stack 220 and the sacrificial layers 206 are replaced with a metal gate structure 252. FIG. 13A illustrates a fragmentary cross-sectional view of the workpiece 200 at block 30 along line A-A of FIG. 3 and in region B of FIG. 4. FIGS. 13B and 13C illustrate enlarged views of a portion B1 of FIG. 13A according to various aspects of the present disclosure. FIGS. 13D and 13F illustrate fragmentary cross-sectional views of the workpiece 200 along line D-D of FIG. 13A and line E-E of FIG. 13B, respectively, according to some aspects of the present disclosure. Line E-E in FIG. 13B is positioned similar to line E-E in FIG. 6B. FIGS. 13E and 13G illustrate fragmentary cross-sectional views of the workpiece 200 along line D-D of FIG. 13A and line E-E of FIG. 13C, respectively, according to some other aspects of the present disclosure. Line E-E in FIG. 13C is positioned similar to line E-E in FIG. 7B.

Operations at block 30 may include depositing a contact etch stop layer (CESL) 244 over the workpiece 200, depositing an interlayer dielectric (ILD) layer 246 over the CESL 244, removing the dummy gate stack 220, selectively removing the sacrificial layers 206 between the channel layers 208 in the channel region 212C, and forming a gate structure 252.

In some embodiments, the CESL 244 is deposited prior to deposition of the ILD layer 246. In some examples, the CESL 244 includes silicon nitride, silicon oxynitride, and/or other materials known in the art. The CESL 244 may be formed by ALD, plasma-enhanced chemical vapor deposition (PECVD) process and/or other suitable deposition processes. The ILD layer 246 is then deposited over the CESL 244. In some embodiments, the ILD layer 246 includes materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The ILD layer 246 may be deposited by a PECVD process or other suitable deposition technique. In some embodiments, after formation of the ILD layer 246, the workpiece 200 may be annealed to improve integrity of the ILD layer 246. As shown in FIGS. 13A, 13D, and 13E, the CESL 244 may be disposed directly on top and side surfaces of the source/drain features 242.

After the deposition of the CESL 244 and the ILD layer 246, the workpiece 200 may be planarized by a planarization process to expose the dummy gate stack 220. For example, the planarization process may include a chemical mechanical planarization (CMP) process. Exposure of the dummy gate stack 220 allows the removal of the dummy gate stack 220. In some embodiments, the removal of the dummy gate stack 220 results in a gate trench over the channel regions 212C. The removal of the dummy gate stack 220 may include one or more etching processes that are selective to the material of the dummy gate stack 220. For example, the removal of the dummy gate stack 220 may be performed using as a selective wet etch, a selective dry etch, or a combination thereof that is selective to the dummy gate stack 220. After the removal of the dummy gate stack 220, sidewalls of the channel layers 208 and the sacrificial layers 206 in the channel region 212C are exposed in the gate trench.

After the removal of the dummy gate stack 220 to form the gate trench, the method 10 selectively removes the sacrificial layers 206 between the channel layers 208 in the channel region 212C. The selective removal of the sacrificial layers 206 releases the channel layers 208 and may be referred to as a channel release process. The selective removal of the sacrificial layers 206 also leave behind space between adjacent channel layers 208. The selective removal of the sacrificial layers 206 may be implemented by selective dry etch, selective wet etch, or other selective etch processes. An example selective dry etching process may include use of one or more fluorine-based etchants, such as fluorine gas or hydrofluorocarbons. An example selective wet etching process may include an APM etch (e.g., ammonia hydroxide-hydrogen peroxide-water mixture).

Because the gate spacers 2260 have an increased thickness (e.g., D6 in FIGS. 11B and 11C) along the X direction adjacent to the sacrificial layers 206 and an interface with the inner spacers 234, during the selective removal of the sacrificial layers 206 in block 30, the thickened gate spacers 2260 may eliminate paths between the sacrificial layers 206 and the source/drain features 242 and provide more protection to the adjacent source/drain features 242, damages (e.g., by an etch solution of the selective etch process) to the source/drain features 242 may be avoided or reduced. In addition, because of the protection provided by the thickened gate spacers 2260, the selective etch processes to remove the sacrificial layers 206 may be performed more thoroughly, reducing amounts of residual sacrificial layers 206 after the selective etch processes. Thus, defects of the semiconductor structure 200 may be reduced. The thickened gate spacers 2260 also provide additional isolation between the source/drain features 242 and the adjacent gate structure 252 (to be described below) and thus may reduce electrical short therebetween.

In some embodiments, the gate structure 252 is formed. The method 10 may include further operations to form the gate structure 252 to wrap around each of the channel layers 208. In some embodiments, the gate structure 252 is formed within the gate trench and into the space left behind by the removal of the sacrificial layers 206. The gate structure 252 includes a gate dielectric layer 254 and a gate electrode layer 256 over the gate dielectric layer 254. In some embodiments, while not explicitly shown in the figures, the gate dielectric layer 254 includes an interfacial layer disposed on the channel layers 208 and a high-K gate dielectric layer over the interfacial layer. High-K dielectric materials, as used and described herein, include dielectric materials having a high dielectric constant, for example, greater than that of thermal silicon oxide (˜3.9). The interfacial layer may include a dielectric material such as silicon oxide, hafnium silicate, or silicon oxynitride. The interfacial layer may be formed by chemical oxidation, thermal oxidation, atomic layer deposition (ALD), chemical vapor deposition (CVD), and/or other suitable method. The high-K gate dielectric layer may include hafnium oxide. Alternatively, the high-K gate dielectric layer may include other high-K dielectric materials, such as titanium oxide (TiO₂), hafnium zirconium oxide (HfZrO), tantalum oxide (Ta₂O₅), hafnium silicon oxide (HfSiO₄), zirconium oxide (ZrO₂), zirconium silicon oxide (ZrSiO₂), lanthanum oxide (La₂O₃), aluminum oxide (Al₂O₃), zirconium oxide (ZrO), yttrium oxide (Y₂O₃), SrTiO₃ (STO), BaTiO₃ (BTO), BaZrO, hafnium lanthanum oxide (HfLaO), lanthanum silicon oxide (LaSiO), aluminum silicon oxide (AlSiO), hafnium tantalum oxide (HfTaO), hafnium titanium oxide (HfTiO), (Ba,Sr)TiO₃ (BST), silicon nitride (SiN), silicon oxynitride (SiON), combinations thereof, or other suitable material. The high-K gate dielectric layer may be formed by ALD, physical vapor deposition (PVD), CVD, oxidation, and/or other suitable methods.

The gate electrode layer 256 of the gate structure 252 may include a single layer or alternatively a multi-layer structure, such as various combinations of a metal layer with a selected work function to enhance the device performance (work function metal layer), a liner layer, a wetting layer, an adhesion layer, a metal alloy or a metal silicide. By way of example, the gate electrode layer 256 may include titanium nitride (TiN), titanium aluminum (TiAl), titanium aluminum nitride (TiAlN), tantalum nitride (TaN), tantalum aluminum (TaAl), tantalum aluminum nitride (TaAlN), tantalum aluminum carbide (TaAlC), tantalum carbonitride (TaCN), aluminum (Al), tungsten (W), nickel (Ni), titanium (Ti), ruthenium (Ru), cobalt (Co), platinum (Pt), tantalum carbide (TaC), tantalum silicon nitride (TaSiN), copper (Cu), other refractory metals, or other suitable metal materials or a combination thereof. In various embodiments, the gate electrode layer 256 may be formed by ALD, PVD, CVD, e-beam evaporation, or other suitable process. In various embodiments, a CMP process may be performed to remove excessive metal, thereby providing a substantially planar top surface of the gate structure 252.

Upon conclusion of the operations at block 30, a GAA transistor 260 is substantially formed. As described above, the GAA transistor 260 may be n-type or p-type. In some embodiments, the gate spacers 2260 include a protruding portion 2260a extending into the gate structure 252. The gate structure 252 tracks the shapes of the dummy gate stack 220 and the sacrificial layers 206 that have been removed in block 30. Thus, as depicted in FIG. 13A, the gate structure 252 includes a first portion between two opposing smooth sidewalls of the gate spacers 2260 (e.g., in a dashed round-cornered rectangle B2), a second portion between two protruding portions 2260a of the gate spacers 2260 (e.g., in a dashed circle B3), and a third portion disposed between two opposing inner spacers 234 (e.g., in a dashed round-cornered rectangle B4). The first portion may be disposed in the gate trench that was formed after the removal of the dummy gate stack 220. The second portion and the third portion may be disposed in the space left behind by the removal of the sacrificial layers 206. In embodiments where block 18 is not omitted, a part of the second portion may also be disposed in the space left behind by the removal of the dummy dielectric layer 216. The first portion has the width D3 along the X direction, the second portion has a width W8 along the X direction, and the third portion has a width W9 along the X direction. In embodiments, W8 is smaller than W3 by about 2 nm to about 6 nm. In embodiments, W8 is smaller than W9 by about 2 nm to about 8 nm. Thus, the second portion is also referred to as a bottleneck portion.

Reference is made to FIGS. 13A, 13B, 13D, and 13F. In these embodiments, the operations of the block 18 is omitted. Each of the channel layers 208 is wrapped around by the gate structure 252. The channel layers 208 extend between two source/drain features 242 along the X direction. As described above, the dashed rectangle 237 in FIG. 13A illustrates the top view position of the channel layers 208. An interface 235 between the gate spacer 2260 and the inner spacer 234 is located within the dashed rectangle 237, thus the interface 235 is disposed between a channel layer 208 and an adjacent channel layer 208 or the base 204. Referring to FIG. 13B, each of the protruding portions 2260a is embedded in the gate structure 252. The protruding portion 2260a has the width D1 as in FIG. 6B, which is the same as a length of the bottleneck portion of the gate structure 252 along the Y direction. Referring to FIG. 13D, the gate structures 252 track the shape of the dummy gate stacks 220 in FIG. 6D. Referring to FIG. 13F, the protruding portions 2260a are directly under the gate structure 252. Each of the protruding portions 2260a is between a channel layer 208 and an adjacent channel layer 208 or the base 204.

Reference is made to FIGS. 13C, 13E, and 13G. In these embodiments, the operations of the block 18 is not omitted. A difference from the embodiments described above regarding FIGS. 13B, 13D, and 13F includes that, the protruding portion 2260a has the width D5′ as in FIG. 7B, which is the same as a length of the bottleneck portion of the gate structure 252 along the Y direction. D5′ is greater than D1, because D5′ is about the sum of D5 and D1. The bottle neck portion of the gate structure 252 may have a stepped profile with a rounded side as shown in FIG. 13C. Referring to FIG. 13E, the gate structures 252 track the shape of the dummy gate stacks 220 in FIG. 7D. Thus, the gate structures 252 include a top portion having the width D9 and a bottom portion having a width D10 along the X direction. In some embodiments, D10 is smaller than D9 by about two times of D4. Accordingly, the adjacent gate spacers 2260 include a bottom portion having a first thickness along the X direction and a top portion having a second thickness along the X direction. The First thickness is greater than the second thickness. Because the protruding portion 2260a fills and tracks the recesses 229 in FIG. 7E, referring to FIG. 13G, the protruding portion 2260a interleaves with the channel layers 208 and surrounds a top surface and sidewalls of the fin-shaped structure 212.

Referring to FIG. 1, method 10 includes a block 32 where further processes are performed to complete the fabrication of the workpiece 200. For example, subsequent processing may form contact openings, contact metal, as well as various contacts/vias/lines and multilayer interconnect features (e.g., metal layers and interlayer dielectrics), configured to connect the various features to form a functional circuit that may include one or more multi-gate devices. The various interconnection features may employ various conductive materials including copper, tungsten, and/or silicide. In one example, a damascene and/or dual damascene process is used to form a copper related multilayer interconnection structure.

Although not intended to be limiting, one or more embodiments of the present disclosure provide many benefits to a semiconductor structure and the formation thereof. For example, embodiments of the present disclosure provide a method to fabricate a semiconductor structure. By performing a recessing process to the sacrificial layer before forming gate spacers, the gate spacers formed thereafter include a protruding portion extending into an adjacent gate structure. The protruding portion of the gate spacers provide more protection to the source/drain features during the channel release process, thus source/drain damage may be avoided and/or reduced, and the removal of sacrificial layers during the channel release process may be more thoroughly performed. The thickened gate spacers may also reduce electrical short between the source/drain features and the gate structure.

In one exemplary aspect, the present disclosure is directed to a method. The method includes providing a workpiece including a stack of semiconductor layers extending lengthwise along a first direction, forming a dummy gate structure to wrap over a channel region of the stack of semiconductor layers and extending lengthwise along a second direction perpendicular to the first direction, after the forming of the dummy gate structure, performing a first etching process to selectively recess the second semiconductor layers, after the first etching process, forming a gate spacer layer over the dummy gate structure and the stack of semiconductor layers, recessing a source/drain region of the stack of semiconductor layers to form a source/drain opening exposing a sidewall of the stack of semiconductor layers, after the recessing of the source/drain region, performing a second etching process to selectively recess the second semiconductor layers from the source/drain opening to form inner spacer recesses, forming inner spacers in the inner spacer recesses, forming a source/drain feature in the source/drain opening, and replacing the dummy gate structure and the second semiconductor layers with a metal gate structure. The stack of semiconductor layers includes first semiconductor layers and second semiconductor layers interleaving with the first semiconductor layers.

In some embodiments, after the performing of the first etching process, in a horizontal plane across one layer of the second semiconductor layers, the one layer has a first width along the first direction and adjacent to the dummy gate structure, and the dummy gate structure has a second width along the first direction, and the second width is greater than the first width. In some embodiments, the performing of the first etching process forms a plurality of first recesses directly under the dummy gate structure, and the forming of the gate spacer layer includes depositing the gate spacer layer in the plurality of first recesses. In some embodiments, presence of the plurality of first recesses causes the stack of semiconductor layers a wavy profile when the stack of semiconductor layers is viewed along the first direction. In some embodiments, the performing of the first etching process includes using a solution including hydrogen fluoride (HF), hydrogen peroxide (H₂O₂), hydrochloric acid (HCl), or a combination thereof. In some embodiments, after the performing of the first etching process, in a cross-sectional view perpendicular to the first direction, the first semiconductor layers have a first width along the second direction and the second semiconductor layers have a second width along the second direction, and the second width is smaller than the first width. In some embodiments, the performing of the first etching process is isotropic. In some embodiments, the forming of the dummy gate structure includes forming a dielectric layer over the stack of semiconductor layers, depositing a polysilicon layer over the dielectric layer, and removing the dielectric layer and the polysilicon layer over the source/drain region of the stack of semiconductor layers. The performing of the first etching process includes a first step to selectively recess the second semiconductor layers, and a second step to selectively recess the dielectric layer. In some embodiments, the second step forms a second recess between the stack of semiconductor layers and the dummy gate structure. In some embodiments, the forming of the gate spacer layer includes depositing the gate spacer layer in the second recess.

In another exemplary aspect, the present disclosure is directed to a method. The method includes providing a workpiece including a first channel layer and a second channel layer extending lengthwise along a first direction, and a sacrificial layer disposed between the first channel layer and the second channel layer. The method further includes forming a dummy gate structure over the first channel layer, the second channel layer, and the sacrificial layer, performing an etching process to selectively and partially recess the sacrificial layer from a first sidewall of the sacrificial layer parallel to the first direction, depositing a gate spacer layer over the dummy gate structure, the first channel layer, the second channel layer, and the sacrificial layer, recessing a source/drain region of the first channel layer, the second channel layer, and sacrificial layer, to form a source/drain opening, and forming a source/drain feature in the source/drain opening. The dummy gate structure extends lengthwise along a second direction perpendicular to the first direction. After the forming of the source/drain feature, a portion of the gate spacer layer is sandwiched between the first channel layer and the second channel layer.

In some embodiments, after the etching process, in a horizontal plane across the sacrificial layer, the sacrificial layer has a first width along the first direction and adjacent the dummy gate structure, and the dummy gate structure has a second width along the first direction, and the first width is smaller than the second width. In some embodiments, after the etching process, in a cross-sectional view perpendicular to the first direction, a second sidewall of the sacrificial layer is recessed from sidewalls of the first channel layer and the second channel layer. In some embodiments, the performing of the etching process includes performing a wet etching process with a solution including hydrogen fluoride (HF), hydrogen peroxide (H₂O₂), hydrochloric acid (HCl), or a combination thereof. In some embodiments, the performing of the etching process forms a recess directly under the dummy gate structure. In some embodiments, the depositing of the gate spacer layer includes depositing the gate spacer layer in the recess.

In yet another exemplary aspect, the present disclosure is directed to a semiconductor structure. The semiconductor structure includes a channel stack including a first channel member and a second channel member, a gate structure disposed around the first channel member and the second channel member and extending lengthwise along a first direction, an inner spacer disposed between the first channel member and the second channel member, and a gate spacer disposed on the gate structure and interfacing the inner spacer. In a horizontal plane between the first channel member and the second channel member, the gate spacer includes a portion protruding into the gate structure along a second direction perpendicular to the first direction.

In some embodiments, the portion of the gate spacer is disposed between the first channel member and the second channel member. In some embodiments, an interface between the inner spacer and the gate spacer is disposed between the first channel member and the second channel member. In some embodiments, in the horizontal plane, the gate structure has a narrowed section adjacent to the portion of the gate spacer.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
providing a workpiece comprising a stack of semiconductor layers extending lengthwise along a first direction, wherein the stack of semiconductor layers comprises first semiconductor layers and second semiconductor layers interleaving with the first semiconductor layers;
forming a dummy gate structure to wrap over a channel region of the stack of semiconductor layers and extending lengthwise along a second direction perpendicular to the first direction;
after the forming of the dummy gate structure, performing a first etching process to selectively recess the second semiconductor layers;
after the first etching process, forming a gate spacer layer over the dummy gate structure and the stack of semiconductor layers;
recessing a source/drain region of the stack of semiconductor layers to form a source/drain opening exposing a sidewall of the stack of semiconductor layers;
after the recessing of the source/drain region, performing a second etching process to selectively recess the second semiconductor layers from the source/drain opening to form inner spacer recesses;
forming inner spacers in the inner spacer recesses;
forming a source/drain feature in the source/drain opening; and
replacing the dummy gate structure and the second semiconductor layers with a metal gate structure.

2. The method of claim 1,
wherein after the performing of the first etching process, in a horizontal plane across one layer of the second semiconductor layers, the one layer has a first width along the first direction and adjacent to the dummy gate structure, and the dummy gate structure has a second width along the first direction,
wherein the second width is greater than the first width.

3. The method of claim 1,
wherein the performing of the first etching process forms a plurality of first recesses directly under the dummy gate structure, and
wherein the forming of the gate spacer layer comprises depositing the gate spacer layer in the plurality of first recesses.

4. The method of claim 3, wherein presence of the plurality of first recesses causes the stack of semiconductor layers a wavy profile when the stack of semiconductor layers is viewed along the first direction.

5. The method of claim 1, wherein the performing of the first etching process comprises using a solution comprising hydrogen fluoride (HF), hydrogen peroxide (H₂O₂), hydrochloric acid (HCl), or a combination thereof.

6. The method of claim 1,
wherein after the performing of the first etching process, in a cross-sectional view perpendicular to the first direction, the first semiconductor layers have a first width along the second direction and the second semiconductor layers have a second width along the second direction,
wherein the second width is smaller than the first width.

7. The method of claim 1, wherein the performing of the first etching process is isotropic.

8. The method of claim 1,
wherein the forming of the dummy gate structure comprises:
forming a dielectric layer over the stack of semiconductor layers,
depositing a polysilicon layer over the dielectric layer, and
removing the dielectric layer and the polysilicon layer over the source/drain region of the stack of semiconductor layers,
wherein the performing of the first etching process comprises:
a first step to selectively recess the second semiconductor layers, and a second step to selectively recess the dielectric layer.

9. The method of claim 8, wherein the second step forms a second recess between the stack of semiconductor layers and the dummy gate structure.

10. The method of claim 9, wherein the forming of the gate spacer layer comprises depositing the gate spacer layer in the second recess.

11. A method, comprising:
providing a workpiece comprising:
a first channel layer and a second channel layer extending lengthwise along a first direction, and
a sacrificial layer disposed between the first channel layer and the second channel layer;
forming a dummy gate structure over the first channel layer, the second channel layer, and the sacrificial layer, wherein the dummy gate structure extends lengthwise along a second direction perpendicular to the first direction;
performing an etching process to selectively and partially recess the sacrificial layer from a first sidewall of the sacrificial layer parallel to the first direction;
depositing a gate spacer layer over the dummy gate structure, the first channel layer, the second channel layer, and the sacrificial layer;
recessing a source/drain region of the first channel layer, the second channel layer, and sacrificial layer, to form a source/drain opening; and
forming a source/drain feature in the source/drain opening,
wherein after the forming of the source/drain feature, a portion of the gate spacer layer is sandwiched between the first channel layer and the second channel layer.

12. The method of claim 11,
wherein after the etching process, in a horizontal plane across the sacrificial layer, the sacrificial layer has a first width along the first direction and adjacent the dummy gate structure, and the dummy gate structure has a second width along the first direction,
wherein the first width is smaller than the second width.

13. The method of claim 11, wherein after the etching process, in a cross-sectional view perpendicular to the first direction, a second sidewall of the sacrificial layer is recessed from sidewalls of the first channel layer and the second channel layer.

14. The method of claim 11, wherein the performing of the etching process comprises performing a wet etching process with a solution comprising hydrogen fluoride (HF), hydrogen peroxide (H₂O₂), hydrochloric acid (HCl), or a combination thereof.

15. The method of claim 11, wherein the performing of the etching process forms a recess directly under the dummy gate structure.

16. The method of claim 15, wherein the depositing of the gate spacer layer comprises depositing the gate spacer layer in the recess.

17. A semiconductor structure, comprising:
a channel stack comprising a first channel member and a second channel member;
a gate structure disposed around the first channel member and the second channel member and extending lengthwise along a first direction;
an inner spacer disposed between the first channel member and the second channel member; and
a gate spacer disposed on the gate structure and interfacing the inner spacer,
wherein in a horizontal plane between the first channel member and the second channel member, the gate spacer comprises a portion protruding into the gate structure along a second direction perpendicular to the first direction.

18. The semiconductor structure of claim 17, wherein the portion of the gate spacer is disposed between the first channel member and the second channel member.

19. The semiconductor structure of claim 17, wherein an interface between the inner spacer and the gate spacer is disposed between the first channel member and the second channel member.

20. The semiconductor structure of claim 17, wherein in the horizontal plane, the gate structure has a narrowed section adjacent to the portion of the gate spacer.
